(19) United States
(12) Patent Application Publication
(10) Pub. No.: US 2018/0314629 A1
(43) Pub. Date: Nov. 1, 2018

(54) MANAGING PARALLEL ACCESS TO A PLURALITY OF FLASH MEMORIES

(71) Applicant: British Cayman Islands Intelligo Technology Inc., Grand Cayman (KY)

(72) Inventors: Jian-Tai CHEN, Zhubei City (TW); Yueh-Nong HONG, Zhubei City (TW); Chen-Chu HSU, Zhubei City (TW); Tsung-Liang CHEN, Zhubei City (TW)

(21) Appl. No.: 15/922,390

(22) Filed: Mar. 15, 2018

Related U.S. Application Data
(60) Provisional application No. 62/491,218, filed on Apr. 27, 2017.

(51) Int. Cl. G06F 12/02; G11C 16/04; G11C 16/08; G11C 16/10; G11C 16/16; G11C 8/12; G06F 12/0866

(52) U.S. Cl. CPC G06F 12/0246; G11C 16/04; G11C 16/08; G06F 12/0866; G11C 16/16; G11C 8/12; G11C 16/102

(57) ABSTRACT

A memory device is disclosed. The memory device comprises N flash memories and a flash manager. The flash manager comprises an interleave/de-interleave buffer and an addressing circuit. The interleave/de-interleave buffer operates according to a mode signal. The addressing circuit sequentially converts N input address signals to transmit N converted address signals. For write operations, the interleave/de-interleave buffer interleaves a write parameter stream into N interleaved streams according to the mode signal indicative of interleave mode and the N interleaved streams in conjunction with the N converted address signals are written into the N flash memories in parallel. For read operations, N read streams are read from the N flash memories in parallel in response to the N converted address signals and the interleave/de-interleave buffer de-interleaves the N read streams into a de-interleaved parameter stream according to the mode signal indicative of de-interleave mode.

### CROSS-REFERENCE TO RELATED APPLICATION

This application claims priority under 35 USC 119(e) to U.S. provisional application No. 62/491,218, filed on Apr. 27, 2017, the content of which is incorporated herein by reference in its entirety.

### BACKGROUND OF THE INVENTION

### Field of the invention

The invention relates to nonvolatile memory systems, and more particularly, to managing parallel access to a plurality of flash memories.

### Description of the Related Art

DRAM (dynamic random access memory) stores each bit of data or program code in a storage cell consisting of a capacitor and a transistor, and is typically organized in a rectangular configuration of storage cells. A DRAM storage cell is dynamic in that it needs to be refreshed or given a new electronic charge every few milliseconds to compensate for charge leaks from the capacitor. The main advantages of DRAM are its simple design and high speed in comparison to alternative types of memory. The main disadvantages of DRAM are volatility, high power consumption and high cost relative to other options.

Flash memory is the least expensive form of semiconductor memory, which is nonvolatile memory that can hold data even without power. Compared to DRAM, flash memory speed is relatively slower. Because of the slower speed, flash memory is used for storage memory, most commonly in devices like solid-state drives. Unlike DRAM, flash memory offers lower power consumption and low cost, and can be erased in large blocks. However, a single flash memory chip generally has a lower bandwidth than a single DRAM chip. Further, in a computer system, such as a neural network computer system, there are normally multiple sets of coefficients/parameters required to be read from and stored into a nonvolatile memory device in real time.

What is needed is a nonvolatile memory device capable of parallel accessing at least one flash memory to increase the memory bandwidth, while maintaining the advantages of non-volatility, low cost and low power consumption of the at least one flash memory.

### SUMMARY OF THE INVENTION

In view of the above-mentioned problems, an object of the invention is to provide a memory device capable of parallel accessing at least one flash memory to increase the memory bandwidth.

One embodiment of the invention provides a memory device. The memory device comprises N flash memories (N>=1) and a flash manager. The flash manager comprises an interleave/de-interleave buffer and an addressing circuit. The interleave/de-interleave buffer operates according to a mode signal. The addressing circuit sequentially converts N input address signals to transmit N converted address signals to the N flash memories. For a write operation, the interleave/de-interleave buffer interleaves a write parameter stream into N interleaved streams according to the mode signal indicative of interleave mode and the N interleaved streams in conjunction with the N converted address signals are written into the N flash memories in parallel. For a read operation, N read streams are read from the N flash memories in parallel in response to the N converted address signals and the interleave/de-interleave buffer de-interleaves the N read streams into a de-interleaved parameter stream according to the mode signal indicative of de-interleave mode.

Another embodiment of the invention provides a computer system. The computer system comprises a CPU and a memory device. The memory device coupled to the CPU comprises N flash memories (N>=1) and a flash manager. The flash manager comprises an interleave/de-interleave buffer and an addressing circuit. The interleave/de-interleave buffer operates according to a mode signal. The addressing circuit sequentially converts N input address signals from the CPU to transmit N converted address signals to the N flash memories. For a write operation, the interleave/de-interleave buffer interleaves a write parameter stream into N interleaved streams according to the mode signal indicative of interleave mode and the N interleaved streams in conjunction with the N converted address signals are written into the N flash memories in parallel. For a read operation, N read streams are read from the N flash memories in parallel in response to the N converted address signals and the interleave/de-interleave buffer de-interleaves the N read streams into a de-interleaved parameter stream according to the mode signal indicative of de-interleave mode.

Another embodiment of the invention provides a neural network computer system. The neural network computer system comprises a CPU, a processor, a decompression/decryption manager and a memory device. The decompression/decryption manager is coupled to the processor and performs decompression/decryption operations over a de-interleaved parameter stream to deliver a decompressed/decrypted parameter stream to the processor. The processor is coupled to the CPU. The memory device is coupled to the CPU and the decompression/decryption manager, and comprises N flash memories (N>=1) and a flash manager. The flash manager comprises an interleave/de-interleave buffer and an addressing circuit. The interleave/de-interleave buffer operates according to a mode signal. The addressing circuit sequentially converts N input address signals from the CPU to transmit N converted address signals to the N flash memories. For a write operation, the interleave/de-interleave buffer interleaves a write parameter stream from the CPU into N interleaved streams according to the mode signal indicative of an interleave mode and the N interleaved streams in conjunction with the N converted address signals are written into the N flash memories in parallel. For a read operation, N read streams are read from the N flash memories in parallel in response to the N converted address signals and the interleave/de-interleave buffer de-interleaves the N read streams into the de-interleaved parameter stream according to the mode signal indicative of a de-interleave mode.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a block diagram showing a computer system according to an embodiment of the invention.

FIG. 2 is a block diagram showing the flash manager 120 according to an embodiment of the invention.

FIG. 3A shows a data-flow diagram for the computer system 100 for a write operation.

FIG. 3B is an example showing a data-flow diagram for a portion of the flash manager and the flash memories for a write operation when N=2.

FIG. 3C is an exemplary timing diagram showing a relationship among the sub-stream and the signals fsn and addn for each flash memory based on FIG. 3B (without the clock signal CK2).

FIG. 4A shows a data-flow diagram for the computer system 100 for a read operation.

FIG. 4B is an example showing a data-flow diagram for a portion of the flash manager and the flash memories for a read operation when N=2.

FIG. 4C is an exemplary timing diagram showing a relationship between the signals fsn and addn (1<=n<=2) for each flash memory based on FIG. 4B (without the clock signal CK2).

FIG. 5 is a block diagram showing a neural network computer system according to another embodiment of the invention.

FIG. 6 is a block diagram showing a computer system according to another embodiment of the invention.

FIG. 7 is a block diagram showing a computer system according to another embodiment of the invention.

### DETAILED DESCRIPTION OF THE INVENTION

As used herein and in the claims, the term “and/or” includes any and all combinations of one or more of the associated listed items. The use of the terms “a” and “an” and “the” and similar referents in the context of describing the invention are to be construed to cover both the singular and the plural, unless otherwise indicated herein or clearly contradicted by context.

A feature of the invention is to read and write coefficients/parameters from/into at least one flash memory in parallel to increase the memory bandwidth. Another feature of the invention is to interleave a coefficient/parameter main stream into a plurality of interleaved sub-streams and then store the interleaved sub-streams into the at least one flash memory in parallel. Another feature of the invention is to read at least one coefficient/parameter sub-stream from the at least one flash memory in parallel and de-interleave the at least one coefficient/parameter sub-stream to obtain a coefficient/parameter main stream.

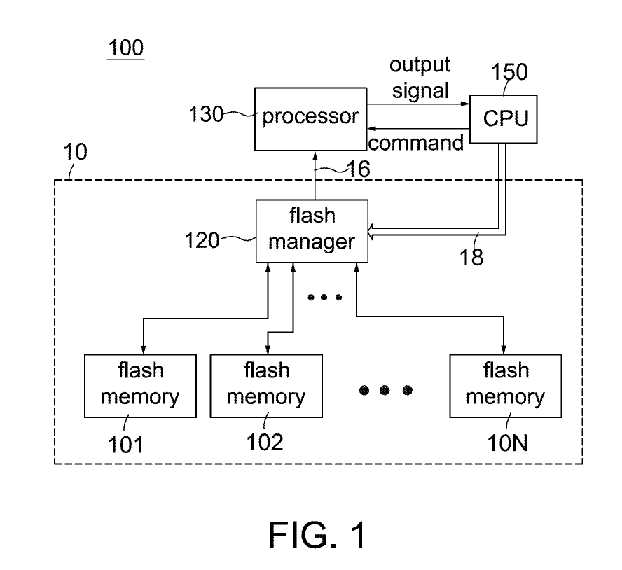

FIG. 1 is a block diagram showing a computer system according to an embodiment of the invention. Referring to FIG. 1, the computer system 100 includes a nonvolatile memory device 10, a processor 130 and a CPU 150. The nonvolatile memory device 10 includes N flash memories 101˜10N (N>=1) and a flash manager 120. In one embodiment, the flash manager 120 and the processor 130 may be integrated into a single chip (not shown), and the N flash memories 101˜10N are located outside the single chip. Throughout the specification, the same components with the same function are designated with the same reference numerals.

The CPU 150 accesses the nonvolatile memory device 10 through a communication link 18. The processor 130 may be any one of a variety of proprietary or commercially available single-processor, multi-processor, digital signal processor (DSP), or graphics processing unit (GPU) able to support specified functions in accordance with each particular embodiment and application. The CPU 150 issues commands to the processor 130 for specified processing tasks and also performs general processing tasks. The processor 130 performs the specified processing tasks (assigned by the CPU 150) over the parameter main stream from the flash memories 101˜10N to generate an output signal to the CPU 150.

The CPU 150 may issue a data request through the communication link 18 to the memory device 10 to perform a data operation. For example, an application executing on the CPU 150 may perform a read or write operation over the memory device 10. In response to the data request, the flash manager 120 manages communications and data operations among the CPU 150, the processor 130 and the N flash memories 101˜10N.

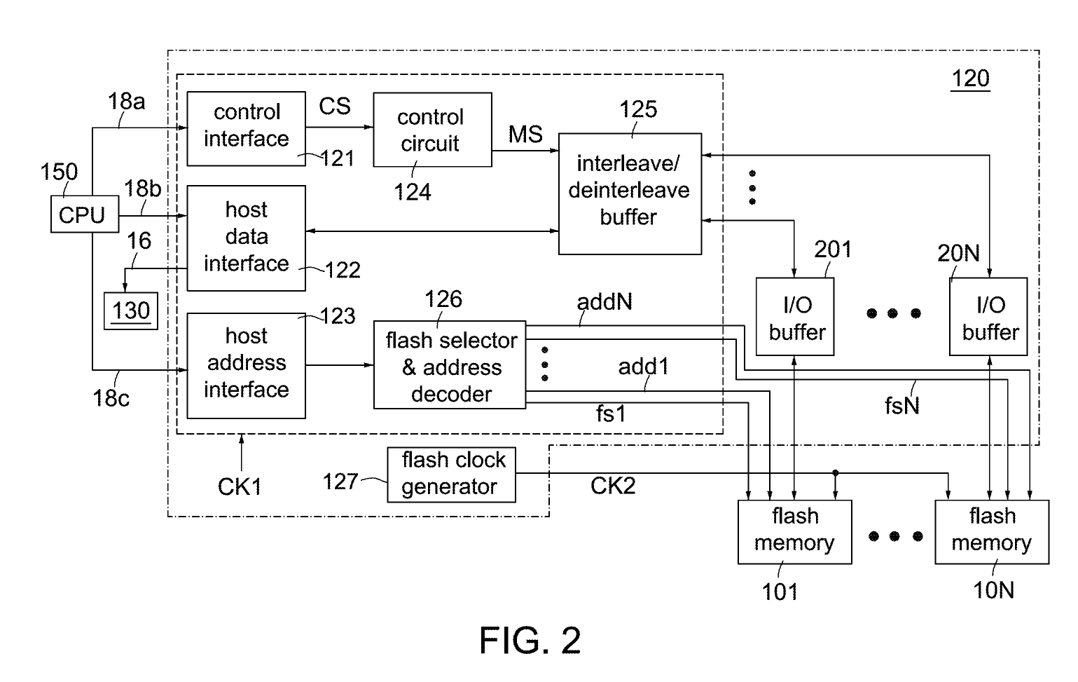

FIG. 2 is a block diagram showing the flash manager 120 according to an embodiment of the invention. Referring to FIG. 2, the flash manager 120 includes a control interface 121, a host data interface 122, a host address interface 123, a control circuit 124, a interleave/de-interleave buffer 125, a flash selector & address decoder 126, a flash clock generator 127 and N input/output (I/O) buffers 201˜20N. The interleave/de-interleave buffer 125 performs an interleave operation on the write data (from the CPU 150 to the flash memories 101˜10N) and performs a de-interleave operation on the reading data (from the flash memories 101˜10N to the processor 130). Here, the control interface 121, the host data interface 122, the host address interface 123, the control circuit 124, the interleave/de-interleave buffer 125 and the flash selector & address decoder 126 operate according to the same clock signal CK1 while the N flash memories 101˜10N operate according to the same clock signal CK2 outputted from the flash clock generator 127. The clock rate of the clock signal CK1 is N times greater than that of the clock signal CK2.

The flash manager 120 includes the control interface 121, the host data interface 122 and the host address interface 123 for connection to the CPU 150 and the processor 130. The communication link 18 is divided into three communication sub-links 18a/b/c. The control interface 121 is used to establish a first communication sub-link 18a between the flash manager 120 and the CPU 150 for transferring buffer mode information. The host data interface 122 is used to establish a second communication sub-link 18b between the flash manager 120 and the CPU 150 for transferring data from the CPU 150 to the N flash memories 101˜10N, and establish a communication link 16 between the flash manager 120 and the processor 130 for transferring data from the N flash memories 101˜10N to the processor 130. The host address interface 123 is used to establish a third communication sub-link 18c between the flash manager 120 and the CPU 150 for transferring flash memory address offset information. Each of the control interface 121, the host data interface 122 and the host address interface 123 may be any type of serial communication interfaces as known to those skilled in the art. Example serial communication interfaces includes, without limitation, Inter-Integrated Circuit (I²C), Inter-IC sound (I²S), and Serial Peripheral Interface (SPI).

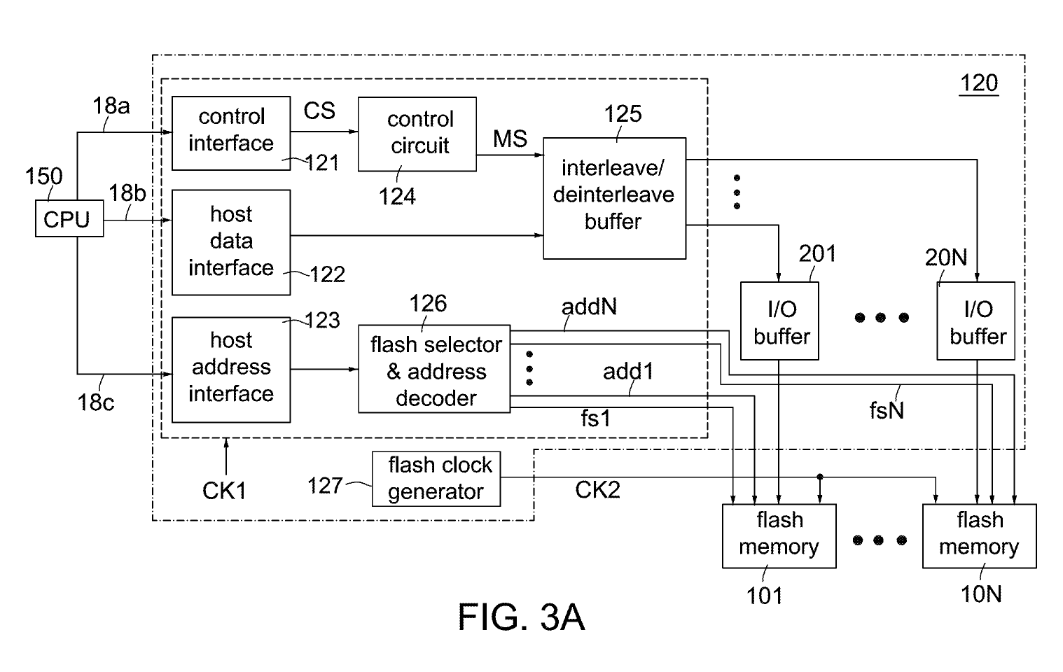

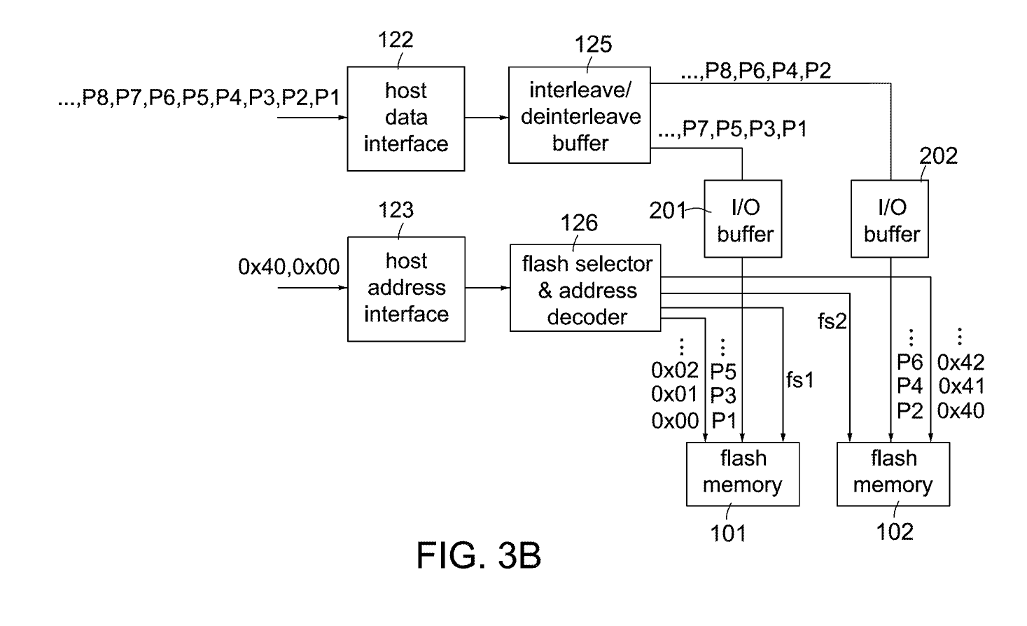

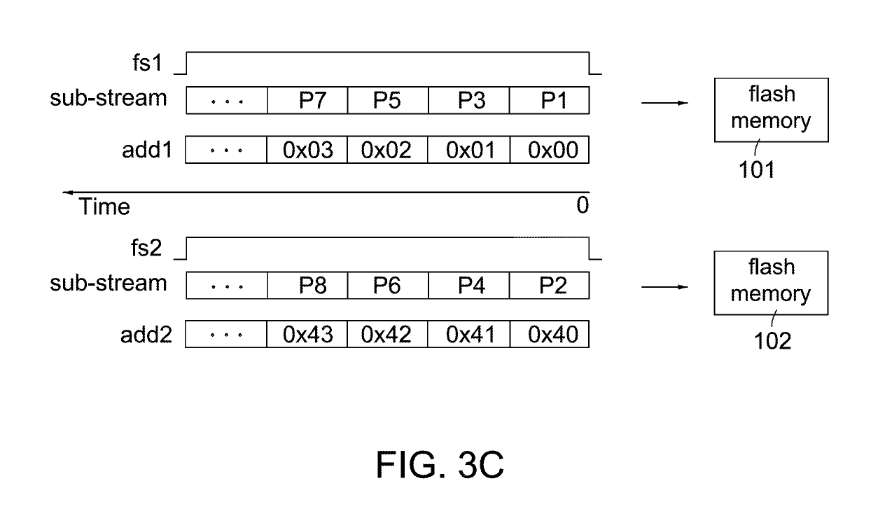

FIG. 3A shows a data-flow diagram for the computer system 100 for a write operation. Referring to FIG. 3A, for a write operation, the CPU 150 issues a control signal CS indicative of an interleave mode to the control circuit 124 through the first communication sub-link 18a and the control interface 121, transfers a parameter main stream to the interleave/de-interleave buffer 125 through the second communication sub-link 18b and the host data interface 122, and transfers N address offsets to the flash selector & address decoder 126 through the third communication sub-link 18c and the host address interface 123. Responsive to the control signal CS indicative of an interleave mode, the control circuit 124 generates a mode signal MS with a first voltage level or a first digital code corresponding to the interleave mode to the interleave/de-interleave buffer 125 to cause the interleave/de-interleave buffer 125 to operate in the interleave mode. Responsive to the mode signal MS with the first voltage level or the first digital code, the interleave/de-interleave buffer 125 operates in the interleave mode, receives a parameter main stream from the host data interface 122 and interleaves the parameter main stream into N interleaved sub-streams to be respectively transmitted to the N I/O buffer 201˜20N. Each of the N I/O buffer 201˜20N collects a corresponding interleaved sub-stream until it is full and then writes its content into a corresponding flash memory 10n at a time, in conjunction with the signals CK2, fsn and addn, where 1<=n<=N. The flash selector & address decoder 126 sequentially receives the N address offsets from the host address interface 123, performs address decoding operations and generates N chip select signals fs1˜fsN and N converted address signals add1˜addN in parallel. For example, assuming that N=4 and the parameter main stream from the CPU 150 is P1,P2,P3,P4,P5,P6,P7,P8, . . . , after the parameter main stream is interleaved into four interleaved sub-streams by the interleave/de-interleave buffer 125, a first interleaved sub-stream to be stored in the flash memory 101 is P1,P5, P9, . . . , a second interleaved sub-stream to be stored in the flash memory 102 is P2,P6, P10, . . . , a third interleaved sub-stream to be stored in the flash memory 103 is P3,P7, P11, . . . , a fourth interleaved sub-stream to be stored in the flash memory 104 is P4,P8, P12, . . . .

FIG. 3B is an example showing a data-flow diagram for a portion of the flash manager and the flash memories for a write operation when N=2. Referring to FIG. 3B, assuming that N=2, and there are two I/O buffers 201˜202 and two flash memories 101˜102 in the memory device 10. Responsive to the mode signal MS corresponding to the interleave mode, the interleave/de-interleave buffer 125 operates in the interleave mode, receives a parameter main stream (P1,P2,P3,P4,P5,P6,P7,P8, . . . ) from the host data interface 122 and interleaves the parameter main stream into two interleaved sub-streams for the two I/O buffer 201˜202. The I/O buffer 201 collects its corresponding interleaved sub-stream (P1,P3,P5,P7, . . . ) until it is full. The I/O buffer 202 collects its corresponding interleaved sub-stream (P2,P4,P6,P8, . . . ) until it is full. The flash selector & address decoder 126 sequentially receives two address offsets (0x00 and 0x40) from the host address interface 123, performs address decoding operations and generates two chip select signals fs1˜fs2 and two converted address signals add1˜add2 in parallel. FIG. 3C is an exemplary timing diagram showing a relationship among the sub-stream and the signals fsn and addn (1<=n<=2) for each flash memory based on FIG. 3B (without the clock signal CK2). Referring to FIG. 3C, during the write operation, the two chip select signals fs1˜fs2 remains at high state. Once the two I/O buffer 201˜202 are full, their contents are respectively written into the two flash memories 101˜102 in conjunction with the signals CK2, fs1, fs2, add1 and add2. Each parameter of the sub-stream is arranged to pair/synchronize with a corresponding converted address signal, such as P1 paired with 0x00, P3 paired with 0x01. In this manner, the parameter main stream is interleaved and then stored in the N flash memories 101˜10N in parallel.

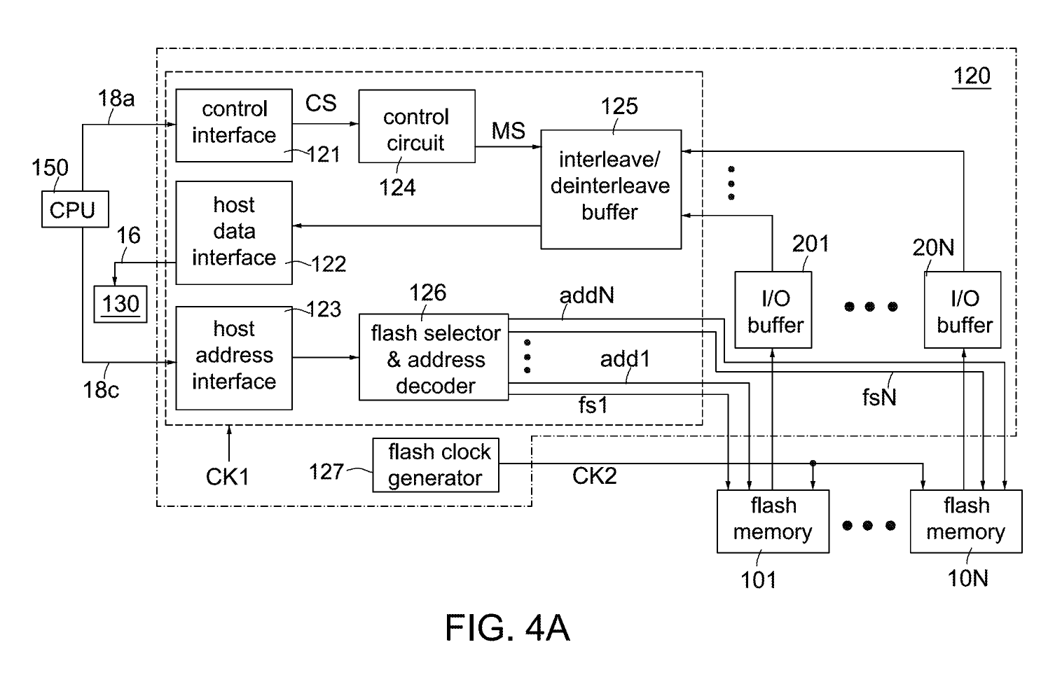

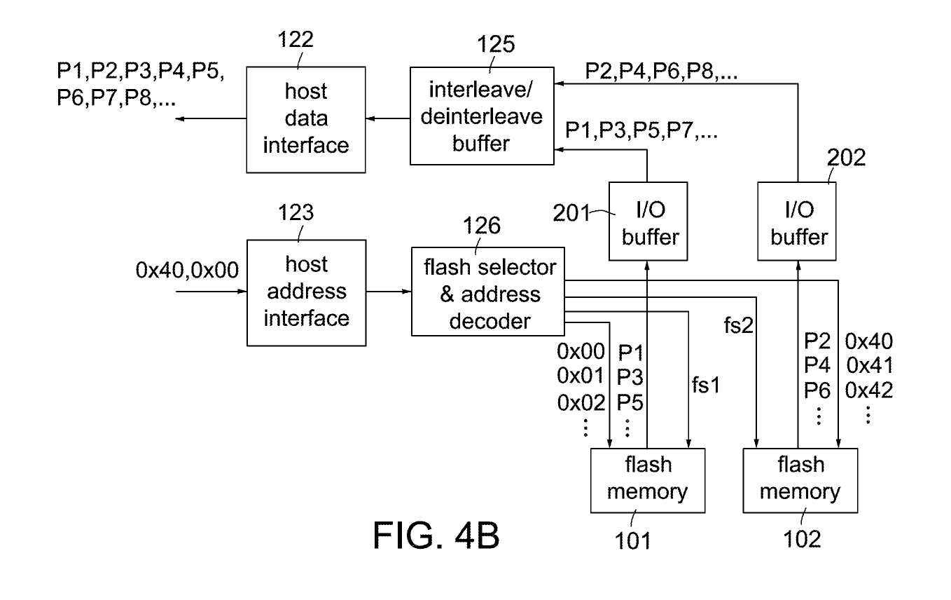

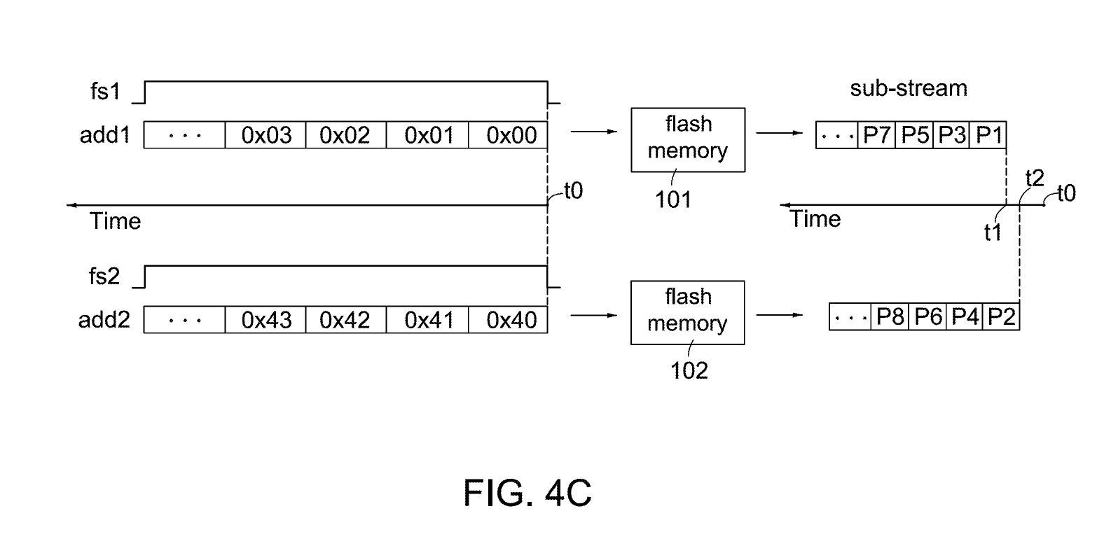

FIG. 4A shows a data-flow diagram for the computer system 100 for a read operation. Referring to FIG. 4A, for a read operation, the CPU 150 issues a control signal CS indicative of a de-interleave mode to the control circuit 124 through the first communication sub-link 18a and the control interface 121, and transfers N address offsets to the flash selector & address decoder 126 through the third communication sub-link 18c and the host address interface 123. Responsive to the control signal CS indicative of a de-interleave mode, the control circuit 124 generates a mode signal MS with a second voltage level or a second digital code to the interleave/de-interleave buffer 125 to cause the interleave/de-interleave buffer 125 to operate in the de-interleave mode. Responsive to the mode signal MS with the second voltage level or the second digital code, the interleave/de-interleave buffer 125 operates in the de-interleave mode. The flash selector & address decoder 126 sequentially receives the N address offsets from the host address interface 123, performs address decoding operations and generates N chip select signals fs1˜fsN and N converted address signals add1˜addN in parallel. After N chip select signals fs1˜fsN and N converted address signals add1˜addN are issued by the flash selector & address decoder 126, N sub-streams are read from the N flash memories 101˜10N in parallel to the interleave/de-interleave buffer 125 through the N I/O buffer 201˜20N and then the N sub-streams are de-interleaved by the interleave/de-interleave buffer 125 to generate a de-interleaved parameter main stream to be transmitted to the processor 130.

FIG. 4B is an example showing a data-flow diagram for a portion of the flash manager and the flash memories for a read operation when N=2. Referring to FIG. 4B, assuming that N=2, and there are two I/O buffers 201˜202 and two flash memories 101˜102 in the memory device 10. Responsive to the mode signal MS with the second voltage level or the second digital code, the interleave/de-interleave buffer 125 operates in the de-interleave mode. FIG. 4C is an exemplary timing diagram showing a relationship between the signals fsn and addn (1<=n<=2) for each flash memory based on FIG. 4B (without the clock signal CK2). Referring to FIG. 4C, after two chip select signals fs1˜fs2 and two converted address signals add1˜add2 are issued by the flash selector & address decoder 126 at t0, a first sub-stream (P1,P3, P5, . . . ) is transferred from the flash memory 101 to the I/O buffer 201 at t1 and a second sub-stream (P2,P4, P6, . . . ) is transferred from the flash memory 102 to the I/O buffer 202 at t2. The I/O buffers 201˜202 respectively collect their corresponding sub-streams until they are full. Once the I/O buffers 201˜202 are full, their contents (the two sub-streams) are sent to the interleave/de-interleave buffer 125. The interleave/de-interleave buffer 125 de-interleaves the two sub-streams to obtain a de-interleaved parameter main stream and then transmits the parameter main stream to the processor 130 through the host data interface 122 and the communication link 16. In this manner, the parameters in the two flash memories 101˜102 are read in parallel and then de-interleaved to obtain a de-interleaved parameter main stream. In the example of FIGS. 3B-3C and 4B-4C, each parameter of the sub-stream has a size of 8-bit (or one byte) and therefore the converted address signal addn is increased by 0x01 at a time. However, the parameter size is only utilized as embodiments and not limitation of the invention. In the actual implementations, any other parameter sizes can be used and this also falls in the scope of the invention. For example, each parameter of the sub-stream may have a size of 16-bit (or one word) and therefore the converted address signal addn is increased by 0x02 at a time.

Although the nonvolatile memory device 10 of the invention is described herein in terms of a general processor-plus-CPU processing architecture, it should be understood that the nonvolatile memory device 10 of the invention is generally applicable to any type of computer systems that need nonvolatile memories.

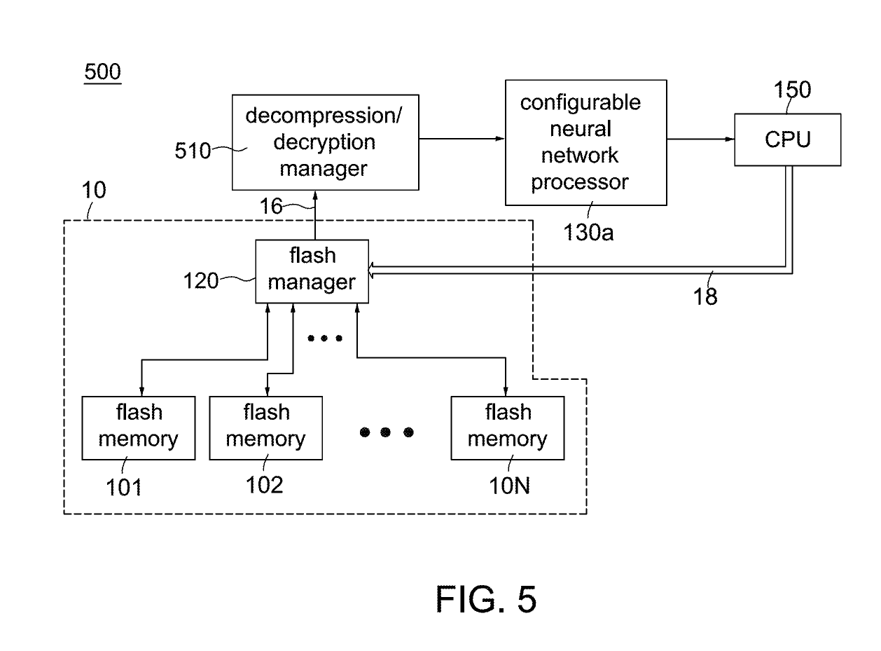

FIG. 5 is a block diagram showing a neural network computer system according to another embodiment of the invention. Referring to FIG. 5, the neural network computer system 500 includes a nonvolatile memory device 10, a configurable neural network processor 130a, a CPU 150 and a decompression/decryption manager 510. In one embodiment, the flash manager 120, the configurable neural network processor 130a and a decompression/decryption manager 510 may be integrated into a single chip (not shown), and the N flash memories 101˜10N are located outside the chip. The operations of the systems 100 and 500 in FIGS. 1 and 5 are similar. The only difference between FIGS. 1 and 5 is found in the addition of a decompression/decryption manager 510 in FIG. 5. Due to the fact that the flash manager 120 is connected to the decompression/decryption manger 510 rather than to the processor 130 in FIG. 5, the flash manager 120 supplies the parameter main stream to the decompression/decryption manger 510 rather than to the processor 130 through the communication link 16 during the read operation. After receiving the parameter main stream, the decompression/decryption manger 510 performs decompression/decryption operations over the parameter main stream to generate a decompressed/decrypted parameter stream and then supplies the decompressed/decrypted parameter stream to the configurable neural network processor 130a. After that, the configurable neural network processor 130a performs specialized neural network functions over the decompressed/decrypted parameter stream to generate an output signal to the CPU 150 for general processing tasks.

The neural network computer system 500 of the invention can be used in a variety of applications that include, without limitation, speaker verification, speaker identification, speaker diarization, audio source separation, audio event detection, sound classification, voice morphing, speech enhancement, far-field audio processing, automatic speech recognition (ASR), text to speech (TTS), image classification, image segmentation, and human detection.

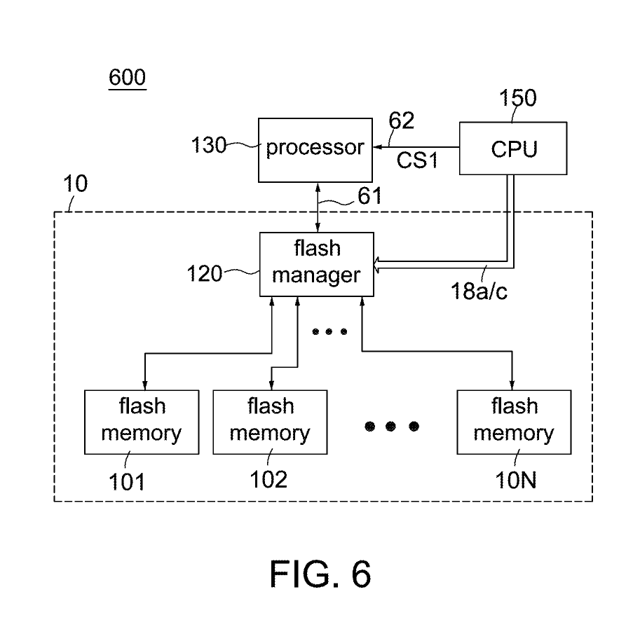

FIG. 6 is a block diagram showing a computer system according to another embodiment of the invention. A communication link 61 is established between the processor 130 and the host data interface 122 of the memory device 10 (not shown). Comparing FIGS. 1 and 6, the differences are as follows. First, the first communication sub-link 18a and the third communication sub-link 18c are still established between the flash manager 120 and the CPU 150 while the second communication sub-link 18b is eliminated in the computer system 600. Second, the communication link 16 (i.e., unidirectional) in the computer system 100 only transfers data from the N flash memories 101˜10N to the processor 130 while the communication link 61 (i.e., bidirectional) in the computer system 600, through the host data interface 122, not only transfers data from the N flash memories 101˜10N to the processor 130, but also writes data from the processor 130 to the N flash memories 101˜10N in conjunction with the first communication sub-link 18a (via the control interface 121) and the third communication sub-link 18c (via the host address interface 123). Third, for a write operation, the CPU 150 in the computer system 600 issues a control signal CS1 (indicative of a start of the write operation) to the processor 130 (e.g., through a serial communication link 62); after receiving the control signal CS1, the processor 130 transfers a parameter main stream to the interleave/de-interleave buffer 125 through the communication link 61 and the host data interface 122; meanwhile, the CPU 150 issues a control signal CS indicative of an interleave mode to the control circuit 124 through the first communication sub-link 18a and the control interface 121, and transfers N address offsets to the flash selector & address decoder 126 through the third communication sub-link 18c and the host address interface 123. Fourth, during a read operation, after the processor 130 receives the parameter main stream from the N flash memories 101˜10N, it is not necessary for the processor 130 to supply any output signal or the parameter main stream to the CPU 150. The other operations of the computer system 600 are the same as those of the computer system 100, and thus their descriptions are omitted herein. Example serial communication link 62 includes, without limitation, Inter-Integrated Circuit (I²C), Inter-IC sound (I²S), and Serial Peripheral Interface (SPI).

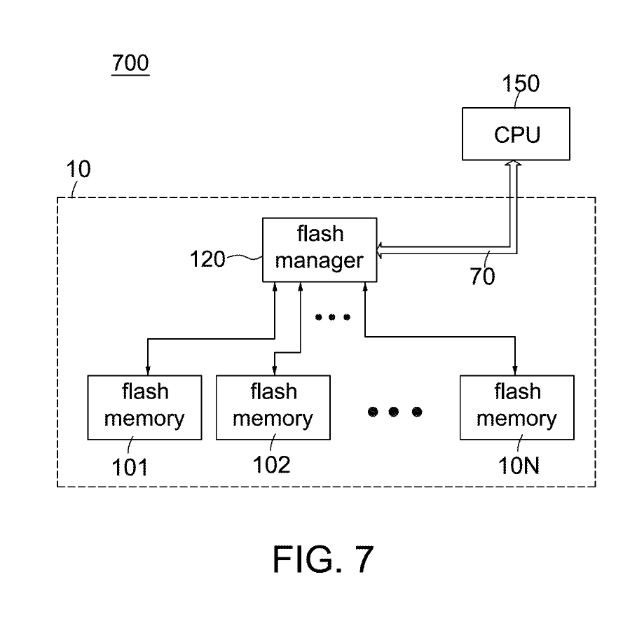

FIG. 7 is a block diagram showing a computer system according to another embodiment of the invention. In comparison with FIG. 1, modification is found in the elimination of the processor 130 and in addition of the communication link 70 in the computer system 700. The communication link 70 is divided into the first communication sub-link 18a, the second communication sub-link 71, and the third communication sub-links 18c. The second communication link 71 is established between the CPU 150 and the host data interface 122 of the memory device 10 (not shown). The communication link 71 (through the host data interface 122) is also bidirectional, i.e., not only transferring data from the N flash memories 101˜10N to the CPU 150, but also writing data from the CPU 150 to the N flash memories 101˜10N in conjunction with the first communication sub-link 18a (via the control interface 121) and the third communication sub-link 18c (via the host address interface 123). The other operations of the computer system 700 are the same as those of the computer system 100, and thus their descriptions are omitted herein.

While certain exemplary embodiments have been described and shown in the accompanying drawings, it is to be understood that such embodiments are merely illustrative of and not restrictive on the broad invention, and that this invention should not be limited to the specific construction and arrangement shown and described, since various other modifications may occur to those ordinarily skilled in the art.

What is claimed is:

1. A memory device, comprising:
N flash memories; and
a flash manager comprising:
an interleave/de-interleave buffer coupled to the N flash memories and operating according to a mode signal; and
an addressing circuit for sequentially converting N input address signals to transmit N converted address signals to the N flash memories;
wherein for a write operation, the interleave/de-interleave buffer interleaves a write parameter stream into N interleaved streams according to the mode signal indicative of an interleave mode and the N interleaved streams in conjunction with the N converted address signals are written into the N flash memories in parallel;
wherein for a read operation, N read streams are read from the N flash memories in parallel in response to the N converted address signals and the interleave/de-interleave buffer de-interleaves the N read streams into a de-interleaved parameter stream according to the mode signal indicative of a de-interleave mode, and wherein N>=1.

2. The device according to claim 1, further comprising:
N input/output buffers, each connected between the interleave/de-interleave buffer and a corresponding flash memory.

3. The device according to claim 1, further comprising:
a control circuit for setting the mode signal to one of the interleave mode and the de-interleave mode according to a control signal.

4. The device according to claim 3, further comprising:
a clock generator for generating a first clock signal and transmitting the first clock signal to the N flash memories;
wherein the interleave/de-interleave buffer, the control circuit and the addressing circuit operate according to a second clock signal; and
wherein the clock rate of the second clock signal is N times greater than that of the first clock signal.

5. The device according to claim 3, further comprising:
a control interface coupled to the control circuit for receiving the control signal;
a data interface coupled to the interleave/de-interleave buffer for receiving the write parameter stream or transmitting the de-interleaved parameter stream; and
an address interface coupled to the addressing circuit for receiving the N input address signals;
wherein each of the control interface, the data interface and the address interface is a serial communication interface.

6. The device according to claim 5, wherein the serial communication interface is selected from a group comprising Inter-Integrated Circuit (I²C), Inter-IC sound (I²S), and Serial Peripheral Interface (SPI).

7. A computer system, comprising:
a CPU; and
a memory device coupled to the CPU, comprising:
N flash memories; and
a flash manager comprising:
an interleave/de-interleave buffer coupled to the N flash memories and operating according to a mode signal; and
an addressing circuit for sequentially converting N input address signals from the CPU to transmit N converted address signals to the N flash memories;
wherein for a write operation, the interleave/de-interleave buffer interleaves a write parameter stream into N interleaved streams according to the mode signal indicative of an interleave mode and the N interleaved streams in conjunction with the N converted address signals are written into the N flash memories in parallel;
wherein for a read operation, N read streams are read from the N flash memories in parallel in response to the N converted address signals and the interleave/de-interleave buffer de-interleaves the N read streams into a de-interleaved parameter stream according to the mode signal indicative of a de-interleave mode, and wherein N>=1.

8. The system according to claim 7, wherein the memory device further comprises:
N input/output buffers, each connected between the interleave/de-interleave buffer and a corresponding flash memory.

9. The system according to claim 7, wherein the memory device further comprises:
a control circuit for setting the mode signal to one of the interleave mode and the de-interleave mode according to a first control signal.

10. The system according to claim 9, wherein the memory device further comprises:
a clock generator for generating a first clock signal and transmitting the first clock signal to the N flash memories;
wherein the interleave/de-interleave buffer, the control circuit and the addressing circuit operate according to a second clock signal; and
wherein the clock rate of the second clock signal is N times greater than that of the first clock signal.

11. The system according to claim 9, wherein the memory device further comprises:
a control interface coupled to the control circuit for transferring the first control signal from the CPU to the control circuit;
a data interface coupled to the interleave/de-interleave buffer for receiving the write parameter stream or transmitting the de-interleaved parameter stream; and
an address interface coupled to the addressing circuit for transferring the N input address signals from the CPU to the addressing circuit;
wherein each of the control interface, the data interface and the address interface is a serial communication interface.

12. The system according to claim 11, wherein the serial communication interface is selected from a group comprising Inter-Integrated Circuit (I²C), Inter-IC sound (I²S), and Serial Peripheral Interface (SPI).

13. The system according to claim 11, wherein the data interface is coupled between the CPU and the interleave/de-interleave buffer, and the data interface is configured to transfer the write parameter stream from the CPU to interleave/de-interleave buffer or transfer the de-interleaved parameter stream from the interleave/de-interleave buffer to the CPU.

14. The system according to claim 11, further comprising:
a processor coupled between the CPU and the memory device.

15. The system according to claim 14, wherein the data interface is coupled among the CPU, the processor and the interleave/de-interleave buffer, and wherein the data interface is configured to transfer the write parameter stream from the CPU to interleave/de-interleave buffer or transfer the de-interleaved parameter stream from the interleave/de-interleave buffer to the processor.

16. The system according to claim 14, wherein the data interface is coupled between the processor and the interleave/de-interleave buffer, wherein the data interface is configured to transfer the write parameter stream from the processor to interleave/de-interleave buffer or transfer the de-interleaved parameter stream from the interleave/de-interleave buffer to the processor, and wherein the processor provides the write parameter stream in response to a second control signal from the CPU.

17. The system according to claim 16, wherein the CPU issues the second control signal to the processor via a serial communication connection.

18. A neural network computer system, comprising:
a CPU;
a processor coupled to the CPU;
a decompression/decryption manager coupled to the processor for performs decompression/decryption operations over a de-interleaved parameter stream to deliver a decompressed/decrypted parameter stream to the processor; and
a memory device coupled to the CPU and the decompression/decryption manager, comprising:
N flash memories; and
a flash manager comprising:
an interleave/de-interleave buffer coupled to the N flash memories and operating according to a mode signal; and
an addressing circuit for sequentially converting N input address signals from the CPU to transmit N converted address signals to the N flash memories;
wherein for a write operation, the interleave/de-interleave buffer interleaves a write parameter stream from the CPU into N interleaved streams according to the mode signal indicative of an interleave mode and the N interleaved streams in conjunction with the N converted address signals are written into the N flash memories in parallel;
wherein for a read operation, N read streams are read from the N flash memories in parallel in response to the N converted address signals and the interleave/de-interleave buffer de-interleaves the N read streams into the de-interleaved parameter stream according to the mode signal indicative of a de-interleave mode, and wherein N>=1.

19. The system according to claim 18, wherein the memory device further comprises:
N input/output buffers, each connected between the interleave/de-interleave buffer and a corresponding flash memory.

20. The system according to claim 18, wherein the memory device further comprises:
a control circuit for setting the mode signal to one of the interleave mode and the de-interleave mode according to a control signal.

21. The system according to claim 20, wherein the memory device further comprises:
a clock generator for generating a first clock signal and transmitting the first clock signal to the N flash memories;
wherein the interleave/de-interleave buffer, the control circuit and the addressing circuit operate according to a second clock signal; and
wherein the clock rate of the second clock signal is N times greater than that of the first clock signal.

22. The system according to claim 20, wherein the memory device further comprises:
a control interface coupled to the control circuit for transferring the control signal from the CPU to the control circuit;
a data interface coupled to the interleave/de-interleave buffer for transferring the write parameter stream from the CPU to the interleave/de-interleave buffer or transferring the de-interleaved parameter stream from the interleave/de-interleave buffer to the decompression/decryption manager; and
an address interface coupled to the addressing circuit for transferring the N input address signals from the CPU to the addressing circuit;
wherein each of the control interface, the data interface and the address interface is a serial communication interface.

23. The system according to claim 22, wherein the serial communication interface is selected from a group comprising Inter-Integrated Circuit (I²C), Inter-IC sound (I²S), and Serial Peripheral Interface (SPI).
